(19) United States
(12) Patent Application Publication
(10) Pub. No.: US 2022/0262604 A1
(43) Pub. Date: Aug. 18, 2022

(54) SUBSTRATE PROCESSING APPARATUS, SUBSTRATE PROCESSING METHOD, METHOD OF MANUFACTURING SEMICONDUCTOR DEVICE AND NON-TRANSITORY COMPUTER-READABLE RECORDING MEDIUM

(71) Applicant: Kokusai Electric Corporation, Tokyo (JP)

(72) Inventor: Naofumi OHASHI, Toyama-shi (JP)

(73) Assignee: Kokusai Electric Corporation, Tokyo (JP)

(21) Appl. No.: 17/670,812

(22) Filed: Feb. 14, 2022

(30) Foreign Application Priority Data
Feb. 15, 2021 (JP) 2021-021963

(51) Int. Cl. H01J 37/32; H01L 21/3065

(52) U.S. Cl. CPC H01J 37/32724; H01L 21/3065; H01J 2237/334; H01J 37/32522; H01J 37/3244

(57) ABSTRACT

There is provided a technique capable of improving uniformity of surface temperature of a substrate in plasma process. According to one aspect thereof, a substrate processing apparatus includes: a process chamber; a substrate support; a first heater in the substrate support for heating a substrate; a second heater for heating an outer periphery of the substrate; a gas supplier for supplying a process gas; a plasma generator; and a controller for performing: (a) heating the substrate to at least a temperature between a first temperature and a second temperature; and (b) supplying the process gas activated by the plasma generator while setting a temperature of the second heater to be higher than that of the second heater at which (a) is performed such that a temperature deviation on a surface of the substrate is within a predetermined temperature deviation range.

### CROSS-REFERENCE TO RELATED PATENT APPLICATION

This non-provisional U.S. patent application claims priority under 35 U.S.C. § 119 of Japanese Patent Application No. 2021-021963, filed on Feb. 15, 2021, in the Japanese Patent Office, the entire contents of which are hereby incorporated by reference.

### BACKGROUND

### 1. Field

The present disclosure relates to a substrate processing apparatus, a substrate processing method, a method of manufacturing a semiconductor device and a non-transitory computer-readable recording medium.

### 2. Related Art

As an apparatus of manufacturing a semiconductor device, a single wafer type apparatus capable of processing a wafer one by one may be used. In the single wafer type apparatus, a gas containing a second element may be supplied onto the wafer after the gas containing the second element is converted into a plasma state.

A plasma process by generating a plasma may be performed. However, since the plasma process may not be uniformly performed on a surface of the wafer (also referred to as a “substrate”), a surface temperature of the substrate may not be uniform when the plasma process is performed. Thereby, the substrate may warp, and a uniformity of the plasma process may deteriorate.

### SUMMARY

According to the present disclosure, there is provided a technique capable of improving a uniformity of a surface temperature of a substrate in a plasma process.

According to one aspect of the technique of the present disclosure, there is provided a substrate processing apparatus including: a process chamber in which a substrate is accommodated; a substrate support provided in the process chamber and on which the substrate is placed; a first heater provided in the substrate support and configured to heat the substrate; a second heater configured to heat an outer periphery of the substrate; a gas supplier through which a process gas is supplied onto the substrate; a plasma generator configured to activate the process gas in the process chamber; and a controller configured to be capable of controlling the first heater, the second heater, the gas supplier and the plasma generator to perform: (a) heating the substrate to at least a temperature between a first temperature and a second temperature; and (b) supplying the process gas activated by the plasma generator while setting a temperature of the second heater to be higher than that of the second heater at which (a) is performed such that a temperature deviation on a surface of the substrate is within a predetermined temperature deviation range.

### BRIEF DESCRIPTION OF THE DRAWINGS

FIG. 1 is a diagram schematically illustrating a configuration of a substrate processing apparatus according to a first embodiment of the present disclosure.

FIG. 2 is a block diagram schematically illustrating a configuration of a controller and related components of the substrate processing apparatus according to the first embodiment of the present disclosure.

FIG. 3 is a flow chart schematically illustrating a substrate processing according to the first embodiment of the present disclosure.

FIGS. 4A and 4B are diagrams schematically illustrating operations of the substrate processing apparatus in the substrate processing according to the first embodiment of the present disclosure, respectively.

FIGS. 5A and 5B are diagrams schematically illustrating other operations of the substrate processing apparatus in the substrate processing according to the first embodiment of the present disclosure, respectively.

FIGS. 6A and 6B are diagrams schematically illustrating still other operations of the substrate processing apparatus in the substrate processing according to the first embodiment of the present disclosure, respectively.

FIG. 7 is a flow chart schematically illustrating a film-forming step of the substrate processing according to the first embodiment of the present disclosure.

FIG. 8 is a diagram schematically illustrating a configuration of a substrate processing apparatus according to a second embodiment of the present disclosure.

### DETAILED DESCRIPTION

<Embodiments>

Hereinafter, one or more embodiments (also simply referred to as “embodiments”) according to the technique of the present disclosure will be described with reference to the drawings.

<First Embodiment of Present Disclosure>

First, a first embodiment of the present disclosure will be described.

(1) Configuration of Substrate Processing Apparatus

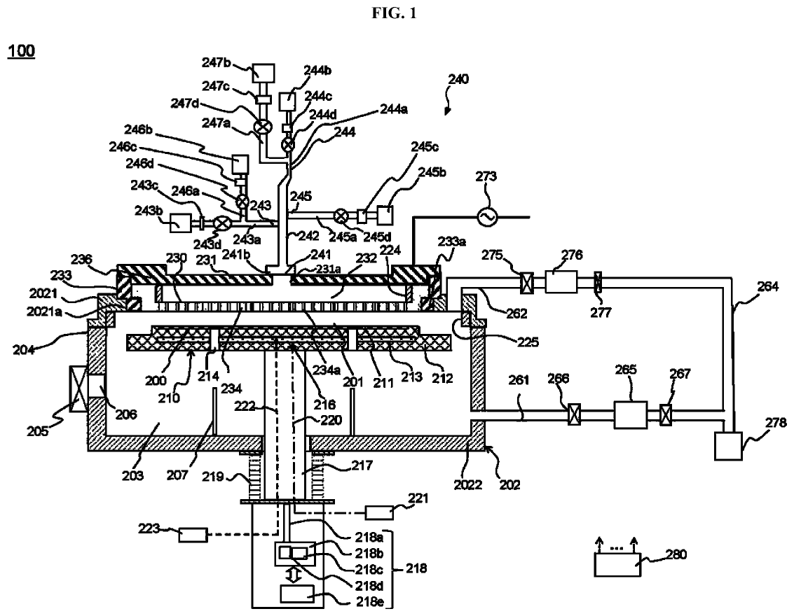

FIG. 1 is a diagram schematically illustrating a configuration of a substrate processing apparatus according to the present embodiment. Hereinafter, the substrate processing apparatus will be described in detail.

<Process Vessel>

As shown in FIG. 1, a substrate processing apparatus 100 includes a process vessel 202. For example, the process vessel 202 is constituted by a flat and sealed vessel whose horizontal cross-section is circular. The process vessel 202 is constituted by an upper vessel 2021 made of a non-metallic material such as quartz and ceramics and a lower vessel 2022 made of a metal material such as aluminum (Al) and stainless steel (SUS). A process space (also referred to as a “process chamber”) 201 in which a wafer (for example, a silicon wafer) 200 serving as a substrate is processed is provided in an upper region (that is, a space above a substrate mounting table 212 described later) of the process vessel 202, and a transfer space 203 is provided below the process chamber 201 in a space surrounded by the lower vessel 2022.

A substrate loading/unloading port 206 is provided adjacent to a gate valve 205 at a side surface of the lower vessel 2022. The wafer 200 is transferred (loaded) into the transfer space 203 through the substrate loading/unloading port 206. A plurality of lift pins 207 are provided at a bottom of the lower vessel 2022. Hereinafter, the plurality of lift pins 207 may also be simply referred to as “lift pins 207”.

<Substrate Support and First Heater>

A substrate support (also referred to as a “susceptor”) 210 configured to support the wafer 200 is provided in the process chamber 201. The substrate support 210 mainly includes: the substrate mounting table 212 provided with a substrate placing surface 211 on which the wafer 200 is placed; and a heater 213 serving as an example of a first heater (which is a first heating structure) provided in the substrate mounting table 212 and configured to heat the wafer 200. Further, the substrate support 210 is provided with a temperature measuring terminal 216 configured to measure a temperature of the heater 213. The temperature measurement terminal 216 is connected to a temperature meter 221 via a wiring 220.

A plurality of through-holes 214 through which the lift pins 207 penetrate are provided at positions of the substrate mounting table 212 corresponding to the lift pins 207. Hereinafter, the plurality of through-holes 214 may also be simply referred to as “through-holes 214”. A wiring 222 through which electric power is supplied is connected to the heater 213. The wiring 222 is connected to a heater power controller 223.

The temperature meter 221 and the heater power controller 223 are electrically connected to a controller 280 described later. The controller 280 is configured to transmit control information to the heater power controller 223 based on temperature information measured by the temperature meter 221. The heater power controller 223 is configured to control the heater 213 with reference to the control information received from the controller 280.

The substrate mounting table 212 is supported by a shaft 217. The shaft 217 penetrates the bottom of the process vessel 202, and is connected to an elevator 218 at the outside of the process vessel 202.

The elevator 218 mainly includes: a support shaft 218a configured to support the shaft 217; and an actuator 218b configured to elevate/lower or rotate the support shaft 218a. For example, the actuator 218b may include: an elevator 218c such as a motor configured to elevate and lower the support shaft 218a; and a rotator 218d such as a gear configured to rotate the support shaft 218a.

The elevator 218 may further include an instruction controller 218e serving as a part of the elevator 218 and configured to control the actuator 218b to move the support shaft 218a up and down or to rotate the support shaft 218a. The instruction controller 218e is electrically connected to the controller 280. The actuator 218b may be controlled by the instruction controller 218e based on an instruction from the controller 280. For example, the actuator 218b is configured to control the substrate mounting table 212 to move to a wafer transfer position or a wafer processing position, as will be described later.

The wafer 200 placed on the substrate placing surface 211 of the substrate mounting table 212 may be elevated or lowered by operating the elevator 218 by elevating or lowering the shaft 217 and the substrate mounting table 212. In addition, a bellows 219 covers a periphery of a lower end of the shaft 217 to maintain the process chamber 201 airtight.

When the wafer 200 is transferred, the substrate mounting table 212 is lowered until the substrate placing surface 211 faces the substrate loading/unloading port 206, that is, until the wafer transfer position is reached. When the wafer 200 is processed, the substrate mounting table 212 is elevated until the wafer 200 reaches a processing position (that is, the wafer processing position) in the process chamber 201.

Specifically, when the substrate mounting table 212 is lowered to the wafer transfer position, upper ends of the lift pins 207 protrude from an upper surface of the substrate placing surface 211, and the lift pins 207 support the wafer 200 from thereunder. In addition, when the substrate mounting table 212 is elevated to the wafer processing position, the lift pins 207 are buried from the upper surface of the substrate placing surface 211 and the substrate placing surface 211 supports the wafer 200 from thereunder.

<Shower Dead>

A shower head 230 serving as a gas dispersion structure is provided at an upper portion of the process chamber 201 (that is, provided at an upstream side of the process chamber 201 in a gas supply direction) so as to face the substrate placing surface 211. The shower head 230 is an example of a part of a gas supplier 240, and is provided so as to face the wafer 200. For example, the shower head 230 is inserted into a hole 2021a provided in the upper vessel 2021.

A lid of the shower head 230 is configured as a plasma generator 231 described later. A block 233 is provided between the plasma generator 231 and the upper vessel 2021. The block 233 electrically and thermally insulates the plasma generator 231 from the upper vessel 2021.

In addition, a through-hole 231a into which a gas supply pipe 241 serving as a first dispersion structure is inserted is provided in the plasma generator 231 of the shower head 230. The gas supply pipe 241 inserted in the through-hole 231a is configured to disperse a gas such as a process gas supplied into a shower head buffer chamber 232 (which is a space provided in the shower head 230). For example, the gas supply pipe 241 is constituted by a front end structure (not shown) inserted into the shower head 230 and a flange 241b fixed to the plasma generator 231. For example, the front end structure (not shown) is of a cylindrical shape, and a dispersion hole (or dispersion holes: not shown) is provided on a side surface of the front end structure (not shown). Then, the gas supplied through the gas supplier (which is a gas supply structure or a gas supply system) 240 described later is supplied into the shower head buffer chamber 232 through the dispersion hole provided in the front end structure (not shown).

In addition, the shower head 230 is provided with a dispersion plate 234 serving as a second dispersion structure configured to disperse the gas supplied through the gas supplier (gas supply system) 240 described later. An upstream side of the dispersion plate 234 is referred to as the shower head buffer chamber 232, and a downstream side of the dispersion plate 234 is referred to as the process chamber 201. The dispersion plate 234 is provided with a plurality of through-holes 234a. Hereinafter, the plurality of through-holes 234a may also be simply referred to as “through-holes 234a ”. The dispersion plate 234 is arranged above the substrate placing surface 211 so as to face the substrate placing surface 211. Therefore, the shower head buffer chamber 232 communicates with the process chamber 201 via the through-holes 234a provided in the dispersion plate 234.

<Second Heater>

In the process chamber 201, heaters 224 and 225 are provided as an example of a second heater (which is a second heating structure) configured to heat an outer periphery of the wafer 200. The heaters 224 and 225 are provided at locations at which the process chamber 201 above the heater 213 of the substrate support 210 shown in FIG. 1 can be heated by the heaters 224 and 225 when the substrate mounting table 212 is elevated to at least the processing position (that is, the wafer processing position).

When the heaters 224 and 225 are provided below the heater 213, the substrate mounting table 212 may be heated. When the substrate mounting table 212 is heated, a temperature of the substrate mounting table 212 becomes non-uniform. Since a heat capacity of the heater 213 and a heat capacity of the substrate mounting table 212 are large, it takes a long time to return to the original temperature. Therefore, a predetermined temperature distribution may not be obtained between a substrate processing and a subsequent substrate processing. Since it takes a long time to return to the predetermined temperature distribution, a waiting time may occur between the substrate processing and the subsequent substrate processing. Further, it takes time to adjust a temperature distribution of the substrate mounting table 212 to the predetermined temperature distribution. Although such problems may occur, by providing the heaters 224 and 225 at the locations where the process chamber 201 above the heater 213 can be heated by the heaters 224 and 225, it is possible to suppress the problems described above from occurring.

According to the present embodiment, it is possible to improve the temperature uniformity of the substrate mounting table 212 and a temperature recoverability of the substrate mounting table 212 (that is, a time for the substrate mounting table 212 to return to its original temperature before the next substrate processing). By improving the temperature recoverability of the substrate mounting table 212, it is possible to shorten the time interval from substrate processing to the subsequent substrate processing, and it is also possible to improve a manufacturing throughput of a semiconductor device.

The heater 225 is provided at a location corresponding to an outer periphery of the substrate support (susceptor) 210. For example, the heater 225 is provided on a surface of a wall of the process chamber 201. Specifically, the heater 225 is provided on an inner peripheral portion of the upper vessel 2021. Thereby, it is possible to suppress an influence of the heater 225 on a gas flow. Further, the wall of the process chamber 201 may be cooled due to the gas flow, and active species may be deactivated in the vicinity of the wall of the process chamber 201. However, by heating the wall of the process chamber 201 by providing the heater 225 on the wall of the process chamber 201, a heat energy is supplied to the active species. As a result, it is possible to prevent (or suppress) the active species from being deactivated.

For example, the heater 224 is provided in the shower head buffer chamber 232 in the gas supplier 240. Specifically, the heater 224 is provided on an inner peripheral portion of the shower head buffer chamber 232. Thereby, it is possible to elevate a temperature of a peripheral portion of the shower head 230. By heating the shower head 230 of the gas supplier 240, it is possible to heat the gas containing the active species. Thereby, the heat energy is supplied to the active species. As a result, it is possible to prevent (or suppress) the active species from being deactivated.

For example, each of the heaters 224 and 225 may be configured as a lamp heater of a ring shape. By configuring each of the heaters 224 and 225 as the lamp heater, it is possible to perform a heating process in a short time. Further, by turning off the lamp heater, it is possible to cool itself (that is, it is possible to return to its original temperature) in a short time.

As the second heater, either one of the heaters 224 and 225 may be provided. The heater 224 may be provided in a surface of a wall of the shower head buffer chamber 232. The heater 225 may be provided in a surface of a wall of the upper vessel 2021.

Plasma Generator>

The plasma generator 231 is configured to activate the process gas in the process chamber 201. The plasma generator 231 shaped as a flat plate is provided above and parallel to the shower head 230, and also serves as the lid for the shower head 230.

Further, for example, the plasma generator 231 includes a resonance coil serving as an electrode, and is configured to plasma-excite the process gas supplied into the process chamber 201 by a high-frequency power supplied from a high frequency power supply 273. A matcher (which is a matching structure) (not shown) capable of matching an impedance and an output frequency of a component such as an RF sensor (not shown) and the high frequency power supply 273 is connected to the plasma generator 231.

<Gas Supplier>

For example, the gas supplier 240 through which the process gas is supplied to the wafer 200 include a first gas supplier (which is a first gas supply structure or a first gas supply system) 243, a second gas supplier (which is a second gas supply structure or a second gas supply system) 244, and a third gas supply supplier (which is a third gas supply structure or a third gas supply system) 245. A common gas supply pipe 242 is connected to the gas supply pipe 241 inserted into the through-hole 231a provided in the plasma generator 231 of the shower head 230. The gas supply pipe 241 and the common gas supply pipe 242 communicate with each other through their inner structures. Further, the gas supplied through the common gas supply pipe 242 is supplied into the shower head 230 through the gas supply pipe 241 and the through-hole (also referred to as a “gas introduction hole”) 231a.

A first gas supply pipe 243a, a second gas supply pipe 244a and a third gas supply pipe 245a are connected to the common gas supply pipe 242.

A first element-containing gas is mainly supplied through the first gas supplier 243 including the first gas supply pipe 243a, and a second element-containing gas is mainly supplied through the second gas supplier 244 including the second gas supply pipe 244a. When processing the wafer 200, an inert gas is mainly supplied through the third gas supplier 245 including the third gas supply pipe 245a, and when cleaning a component such as the shower head 230 and the process chamber 201, a cleaning gas is mainly supplied through the third gas supplier 245.

<First Gas Supplier>

A first gas supply source 243b, a mass flow controller (MFC) 243c serving as a flow rate controller (flow rate control structure) and a valve 243d serving as an opening/closing valve are sequentially provided in this order at the first gas supply pipe 243a from an upstream side toward a downstream side of the first gas supply pipe 243a in a gas flow direction. A gas containing a first element (hereinafter, also referred to as the “first element-containing gas” or a “first gas”) is supplied into the shower head 230 from the first gas supply source 243b through the first gas supply pipe 243a provided with the MFC 243c and the valve 243d and the common gas supply pipe 242.

The first element-containing gas serves as a source gas, which is one of process gases. According to the present embodiment, for example, the first element is silicon (Si). That is, for example, the first element-containing gas includes a silicon-containing gas. A source material of the first element-containing gas may be in a solid state, a liquid state or a gaseous state under the normal temperature and the normal pressure. When the source material of the first element-containing gas is in a liquid state under the normal temperature and the normal pressure, a vaporizer (not shown) may be provided between the first gas supply source 243b and the MFC 243c. Hereinafter, the present embodiment will be described in detail by way of an example in which the source material of the first element-containing gas is in a gaseous state under the normal temperature and the normal pressure.

A downstream end of a first inert gas supply pipe 246a is connected to the first gas supply pipe 243a downstream of the valve 243d provided at the first gas supply pipe 243a. An inert gas supply source 246b, a mass flow controller (MFC) 246c and a valve 246d serving as an opening/closing valve are sequentially provided in this order at the first inert gas supply pipe 246a from an upstream side toward a downstream side of the first inert gas supply pipe 246a in the gas flow direction. The inert gas is supplied into the shower head 230 from the inert gas supply source 246b through the first inert gas supply pipe 246a provided with the MFC 246c and the valve 246d, the first gas supply pipe 243a and the common gas supply pipe 242.

According to the present embodiment, the inert gas acts as a carrier gas of the first element-containing gas. It is preferable that a gas that does not react with the first element is used as the inert gas. Specifically, for example, nitrogen (N₂) gas may be used as the inert gas. Alternatively, instead of the N₂ gas, a rare gas such as helium (He) gas, neon (Ne) gas and argon (Ar) gas may be used as the inert gas.

The first gas supplier (also referred to as a “silicon-containing gas supplier”, a “silicon-containing gas supply structure”, or a “silicon-containing gas supply system”) 243 is constituted mainly by the first gas supply pipe 243a, the MFC 243c and the valve 243d. A first inert gas supplier (which is a first inert gas supply structure or a first inert gas supply system) is constituted mainly by the first inert gas supply pipe 246a, the MFC 246c and the valve 246d.

The first gas supplier 243 may further include the first gas supply source 243b and the first inert gas supplier. In addition, the first inert gas supplier may further include the inert gas supply source 246b and the first gas supply pipe 243a. Since the source gas (which is one of the process gases) is supplied through the first gas supplier 243, the first gas supplier 243 is a part of a process gas supplier (also referred to as a “process gas supply structure” or a “process gas supply system”).

<Second Gas Supplier>

A second gas supply source 244b, a mass flow controller (MFC) 244c serving as a flow rate controller (flow rate control structure) and a valve 244d are sequentially provided in this order at the second gas supply pipe 244a from an upstream side toward a downstream side of the second gas supply pipe 244a in the gas flow direction. A gas containing a second element (hereinafter, also referred to as the “second element-containing gas” or a “second gas”) is supplied into the shower head 230 from the second gas supply source 244b through the second gas supply pipe 244a provided with the MFC 244c and the valve 244d, the plasma generator 231 and the common gas supply pipe 242. When the second element-containing gas is supplied into the shower head 230, the second element-containing gas in a plasma state, which is activated by the plasma generator 231, is supplied onto the wafer 200.

The second element-containing gas serves as a reactive gas or a modifying gas, which is one of the process gases. According to the present embodiment, for example, the second element-containing gas contains the second element different from the first element described above. For example, the second element is one of oxygen (0), nitrogen (N) and carbon (C). According to the present embodiment, for example, a nitrogen-containing gas may be used as the second element-containing gas. Specifically, for example, ammonia (NH₃) gas may be used as the nitrogen-containing gas.

A downstream end of a second inert gas supply pipe 247a is connected to the second gas supply pipe 244a downstream of the valve 244d provided at the second gas supply pipe 244a. An inert gas supply source 247b, a mass flow controller (MFC) 247c and a valve 247d are sequentially provided in this order at the second inert gas supply pipe 247a from an upstream side toward a downstream side of the second inert gas supply pipe 247a in the gas flow direction. The inert gas is supplied into the shower head 230 from the inert gas supply source 247b through the second inert gas supply pipe 247a provided with the MFC 247c and the valve 247d, the second gas supply pipe 244a and the common gas supply pipe 242.

According to the present embodiment, the inert gas acts as a carrier gas of the second element-containing gas or a dilution gas of the second element-containing gas in the substrate processing described later. Specifically, for example, the N₂ gas may be used as the inert gas. Alternatively, instead of the N₂ gas, a rare gas such as helium (He) gas, neon (Ne) gas and argon (Ar) gas may be used as the inert gas.

The second gas supplier (also referred to as a “nitrogen-containing gas supplier”, a “nitrogen-containing gas supply structure”, or a “nitrogen-containing gas supply system”) 244 is constituted mainly by the second gas supply pipe 244a. the MFC 244c and the valve 244d. A second inert gas supplier (which is a second inert gas supply structure or a second inert gas supply system) is constituted mainly by the second inert gas supply pipe 247a, the MFC 247c and the valve 247d.

The second gas supplier 244 may further include the second gas supply source 244b and the second inert gas supplier. In addition, the second inert gas supplier may further include the inert gas supply source 247b and the second gas supply pipe 244a.

Since the second gas supplier 244 is configured to supply the reactive gas or the modifying gas, which is one of the process gases, the second gas supplier 244 is a part of the process gas supplier.

<Third Gas Supplier>

A third gas supply source 245b, a mass flow controller (MFC) 245c and a valve 245d are sequentially provided in this order at the third gas supply pipe 245a from an upstream side toward a downstream side of the third gas supply pipe 245a in the gas flow direction. The inert gas is supplied into the shower head 230 from the third gas supply source 245b through the third gas supply pipe 245a provided with the MFC 245c and the valve 245d and the common gas supply pipe 242.

In the substrate processing described later, the inert gas supplied into the shower head 230 from the third gas supply source 245b acts as a purge gas (also referred to as a “third gas”) of purging a gas remaining in the process vessel 202 or in the shower head 230. Specifically, for example, the N₂ gas may be used as the inert gas. Alternatively, instead of the N₂ gas, a rare gas such as helium (He) gas, neon (Ne) gas and argon (Ar) gas may be used as the inert gas.

The first gas supplier 243, the second gas supplier 244 and the third gas supplier 245 may be collectively referred to as the “process gas supplier” or the “process gas supply system”. Further, the gases supplied through the process gas supplier may also be collectively or individually referred to as the “process gas”.

<Gas Exhauster>

A gas exhauster (which is a gas exhaust structure or a gas exhaust system) through which an inner atmosphere of the process vessel 202 is exhausted may include a plurality of exhaust pipes connected to the process vessel 202. Specifically, the gas exhauster may include an exhaust pipe (also referred to as a “first exhaust pipe”) 261 connected to the transfer space 203 and an exhaust pipe (also referred to as a “second exhaust pipe”) 262 connected to the process chamber 201. In addition, an exhaust pipe (also referred to as a “third exhaust pipe”) 264 is connected to a downstream side of each of the exhaust pipes 261 and 262.

The exhaust pipe 261 is connected to a side surface or a bottom surface of the transfer space 203. The exhaust pipe 261 is provided with a TMP (Turbo Molecular Pump, hereinafter, also referred to as a “first vacuum pump”) 265 serving as a vacuum pump capable of implementing a high vacuum or an ultra-high vacuum. A valve 266 serving as an opening/closing valve is provided at the exhaust pipe 261 upstream of the TMP 265, and a valve 267 serving as an opening/closing valve is provided at the exhaust pipe 261 downstream of the TMP 265.

The exhaust pipe 262 is connected to the process chamber 201 at a side portion of the process chamber 201. An APC (Automatic Pressure Controller) 276 serving as a pressure controller (which is a pressure regulator) configured to adjust (control) an inner pressure of the process chamber 201 to a predetermined pressure is provided at the exhaust pipe 262. The APC 276 includes a valve body (not shown) capable of adjusting an opening degree thereof. The APC 276 is configured to adjust a conductance of the exhaust pipe 262 in accordance with an instruction from the controller 280 described later. In addition, a valve 275 serving as an opening/closing valve is provided at the exhaust pipe 262 upstream of the APC 276, and a valve 277 serving as an opening/closing valve is provided at the exhaust pipe 262 downstream of the APC 276.

A dry pump (DP) 278 is provided at the exhaust pipe 264. As shown in FIG. 1, the exhaust pipes 262 and 261 are connected to an upstream side of the exhaust pipe 264 and the DP 278 is provided at a downstream side of a location where the exhaust pipes 262 and 261 are connected to the exhaust pipe 264. The DP 278 exhausts inner atmospheres of the process chamber 201 and the transfer space 203 through the exhaust pipe 262 and the exhaust pipe 261, respectively. When the TMP 265 is operated, the DP 278 may serve as an auxiliary pump for the TMP 265. That is, since it is difficult for the TMP 265, which is a high vacuum pump (or an ultra-high vacuum pump), to exhaust the inner atmospheres to an atmospheric pressure by itself, the DP 278 is used as the auxiliary pump so as to assist the TMP 265 in exhausting the inner atmospheres to the atmospheric pressure.

<Controller>

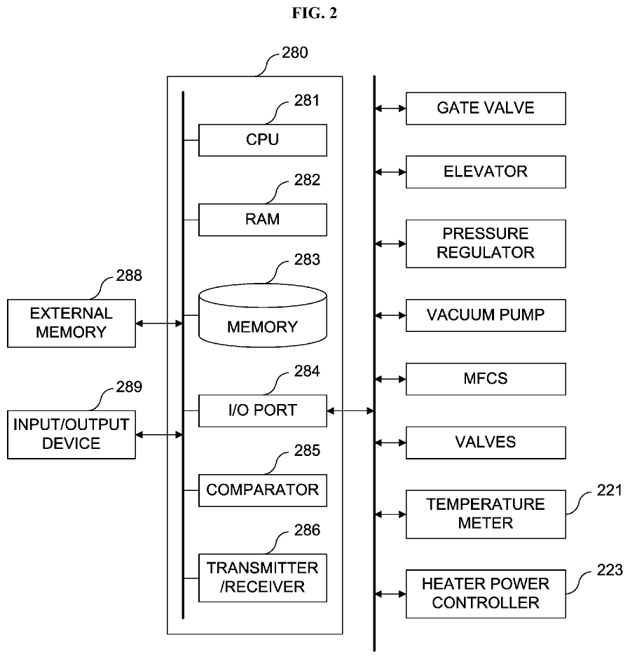

As shown in FIG. 1, the substrate processing apparatus 100 includes the controller 280, which is an example of a control structure (or a control system) configured to control operations of components constituting the substrate processing apparatus 100. As shown in FIG. 2, the controller 280 includes at least a CPU (Central Processing Unit) 281 serving as an operation processor, a RAM (Random Access Memory) 282 serving as a temporary memory, a memory 283, an I/O port 284, a comparator (which is a comparison processor) 285 and a transmitter/receiver (which is a transmitting and receiving processor) 286. The controller 280 is connected to the components described above, calls data such as a program, a recipe and a table from the memory 283 in accordance with an instruction from a host controller (not shown) or a user, and controls the operations of the components constituting the substrate processing apparatus 100 in accordance with contents of the data such as the program, the recipe and the table. The controller 280 further includes an input/output device 289.

For example, the controller 280 is configured to be capable of controlling the heater 213 (that is, the first heater), the heaters 224 and 225 (that is, the second heater), the gas supplier 240 and the plasma generator 231 so as to perform a first processing step S104 and a second processing step S105.

The first processing step S104 is a step of heating the wafer 200 to at least a temperature between a first temperature and a second temperature. The first temperature is measured on a center portion of the wafer 200. The temperature on the center portion of the wafer 200 is mainly controlled (or adjusted) by the heater 213 (that is, the first heater). The second temperature is measured on an outer peripheral portion of the wafer 200. The temperature on the outer peripheral portion of the wafer 200 is mainly controlled by the heaters 224 and 225 (that is, the second heater).

The second processing step S105 is a step of supplying the process gas activated by the plasma generator 231, in which temperatures of the heaters 224 and 225 (that is, the second heater) are set to be higher than those of the heaters 224 and 225 (that is, the second heater) at which the first processing step S104 is performed, such that a temperature deviation on a surface of the wafer 200 is within a predetermined temperature deviation range. In the present embodiment, the term “temperature deviation” refers to a difference between the first temperature and the second temperature. In addition, in the present embodiment, “supplying the process gas activated by the plasma generator 231” may be rephrased as “activating the process gas supplied into the process chamber 201”.

Specifically, the controller 280 (that is, the control structure) is configured to change a pre-set value of the temperature deviation based on substrate data including at least one among a thickness distribution of a film formed on the wafer 200 and a wafer etching rate (WER). More specifically, based on the substrate data including at least one among the thickness distribution of the film formed on the wafer 200 and the wafer etching rate, the controller 280 (that is, the control structure) is configured to change at least one among a pre-set temperature value of the heater 213 (that is, the first heater) and a pre-set temperature value of the heaters 224 and 225 (that is, the second heater).

An amount of the active species may affect film characteristics. However, it is difficult to measure the amount of the active species. Therefore, at least one among the heater 213 and the heaters 224 and 225 are feedback-controlled based on the film characteristics. For example, when the wafer etching rate on the outer peripheral portion of the wafer 200 is high, the temperatures of the heaters 224 and 225 (that is, the second heater) are elevated. Thereby, it is possible to improve an accuracy of controlling the temperature distribution on the surface of the wafer 200.

The controller 280 is not limited to a dedicated computer, and may be embodied by a general-purpose computer. For example, the controller 280 may be embodied by preparing an external memory 288 (for example, a magnetic tape, a magnetic disk such as a flexible disk and a hard disk, an optical disk such as a CD and a DVD, a magneto-optical disk such as an MO, a semiconductor memory such as a USB memory (USB flash drive) and a memory card) where the above-described program is stored and installing the program onto the general-purpose computer using the external memory 288.

A method of providing the program to the computer is not limited to using the external memory 288. For example, the program may be supplied to the computer (general-purpose computer) using communication means such as the Internet and a dedicated line instead of the external memory 288. Further, the memory 283 or the external memory 288 may be embodied by a non-transitory computer readable recording medium. Hereafter, the memory 283 and the external memory 288 may be collectively or individually referred to as a “recording medium”. Thus, in the present specification, the term “recording medium” may refer to the memory 283 alone, may refer to the external memory 288 alone or may refer to both of the memory 283 and the external memory 288. The transmitter/receiver 286 may exchange information with the components described above via the I/O port 284. For example, the transmitter/receiver 286 may receive temperature information from the temperature meter 221. The comparator 285 is configured to compare information such as the table read from the memory 283 with the information received from the components described above, and extracts control parameters for the components described above. For example, the information received from the temperature meter 221 is compared with the table recorded in the memory 283, and a control parameter for operating a component such as the heater power controller 223 is extracted.

(2) Substrate Processing

Hereinafter, as a part of a manufacturing process of the semiconductor device, a process (that is, the substrate processing) of forming the film on the wafer 200 using the substrate processing apparatus 100 will be described. In the following description, the operations of the components constituting the substrate processing apparatus 100 are controlled by the controller 280.

In the following description, an example of forming a silicon nitride film (also simply referred to as an “SiN film”) serving as a semiconductor-based film on the wafer 200 by alternately supplying the first element-containing gas (also referred to as a “first process gas”) and the second element-containing gas (also referred to as a “second process gas”) to the wafer 200 will be described. For example, dichlorosilane (SiH₂Cl₂, abbreviated as DCS) gas is used as the first element-containing gas, and the ammonia (NH₃) gas is used as the second element-containing gas.

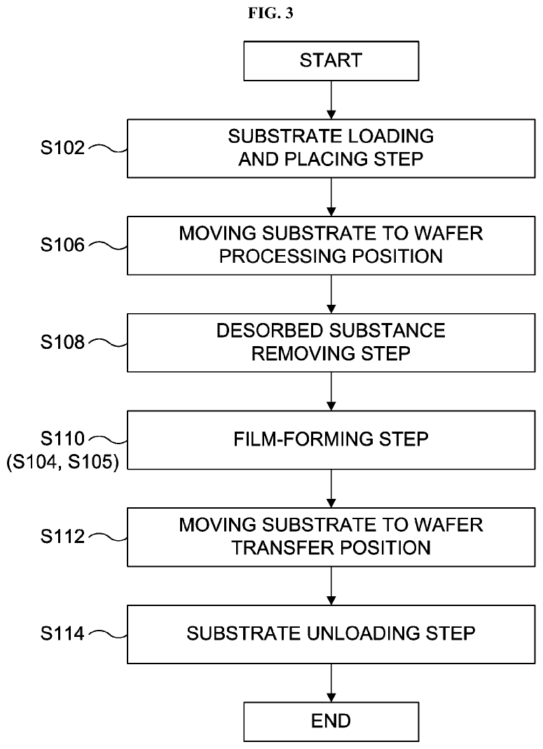

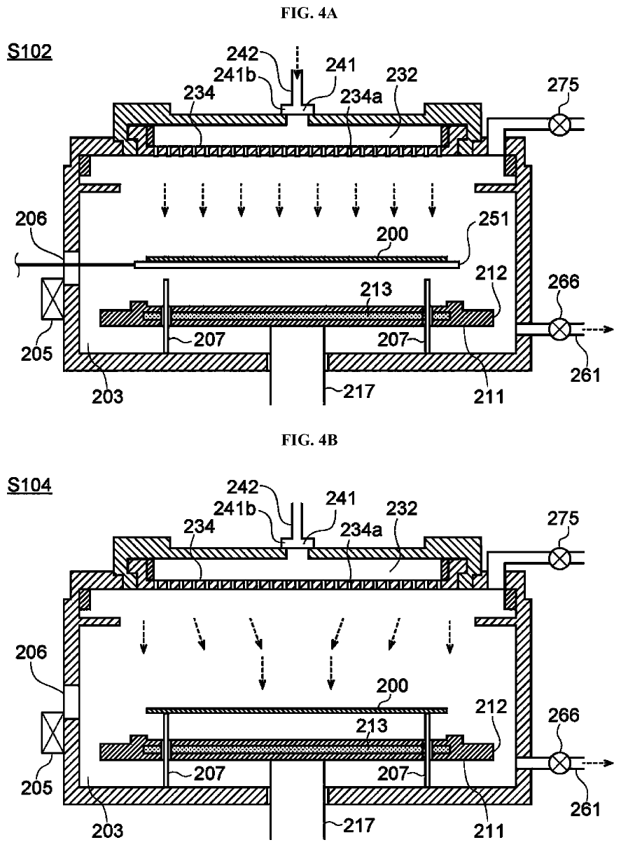

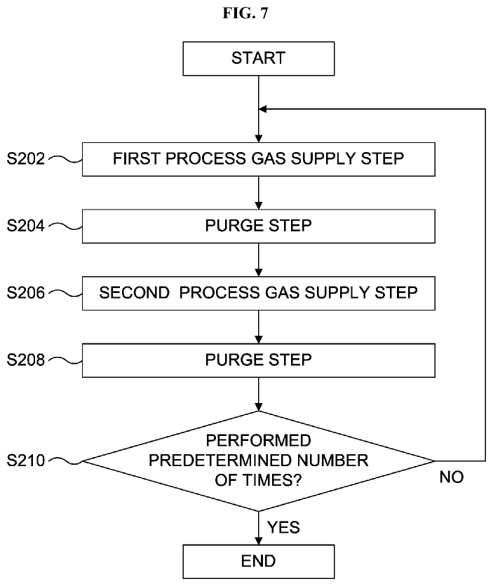

FIG. 3 is a flowchart schematically illustrating the substrate processing according to the present embodiment. FIGS. 4A through 6B are diagrams schematically illustrating other operations of the substrate processing apparatus 100 in the substrate processing, respectively. FIG. 7 is a flow chart schematically illustrating a film-forming step of the substrate processing shown in FIG. 3.

In general, when the wafer 200 is suddenly heated from a back surface thereof, a temperature difference between a front surface and the back surface of the wafer 200 becomes large. Due to the temperature difference, the elongation of the surface differs between the front surface and the back surface of the wafer 200. As a result, the wafer 200 may warp. It can be considered that the characteristics of the film formed on the wafer 200 are affected when the wafer 200 warps.

As a method of avoiding a warp of the wafer 200, the wafer 200 may be gradually heated. However, when the wafer 200 is gradually heated, it takes time to adjust the temperature of the wafer 200 to a desired temperature, and a throughput (that is, the manufacturing throughput) is lowered.

Therefore, according to the present embodiment, a technique capable of suppressing the warp of the wafer 200 while maintaining the throughput at a high level is provided. Hereinafter, the substrate processing according to the technique will be described in detail.

<Substrate Loading and Placing Step: S102>

Since it takes time for the heater 213 and the heaters 224 and 225 to stabilize their operations, according to the present embodiment, the heater 213 and the heaters 224 and 225 are turned on before the wafer 200 is transferred (loaded) into a vacuum transfer chamber (not shown). After the heater 213 and the heaters 224 and 225 are stabilized, the substrate mounting table 212 is lowered to the wafer transfer position at which the wafer 200 can be transferred such that the lift pins 207 penetrate the through-holes 214 of the substrate mounting table 212. As a result, the lift pins 207 protrude from a surface of the substrate mounting table 212 by a predetermined height. In parallel with an operation of lowering the substrate mounting table 212, an inner atmosphere of the transfer space 203 is exhausted such that an inner pressure of the transfer space 203 is the same as that of the vacuum transfer chamber provided adjacent thereto or is lower than that of the vacuum transfer chamber provided adjacent thereto.

Subsequently, the gate valve 205 is opened such that the transfer space 203 communicates with the adjacent vacuum transfer chamber (not shown). Then, the wafer 200 is transferred (loaded) into the transfer space 203 from the vacuum transfer chamber using a vacuum transfer robot 251 as shown in FIG. 4A, and placed onto the lift pins 207 as shown in FIG. 4B. In the substrate loading and placing step S102, by supplying the inert gas into the process chamber 201 and the transfer space 203 through the third gas supplier 245 and exhausting the inner atmospheres of the process chamber 201 and the transfer space 203 through the exhaust pipe 261, it is possible to prevent an outside atmosphere from entering the process chamber 201 and the transfer space 203.

<Step of Moving Substrate to Wafer Processing Position: S106>

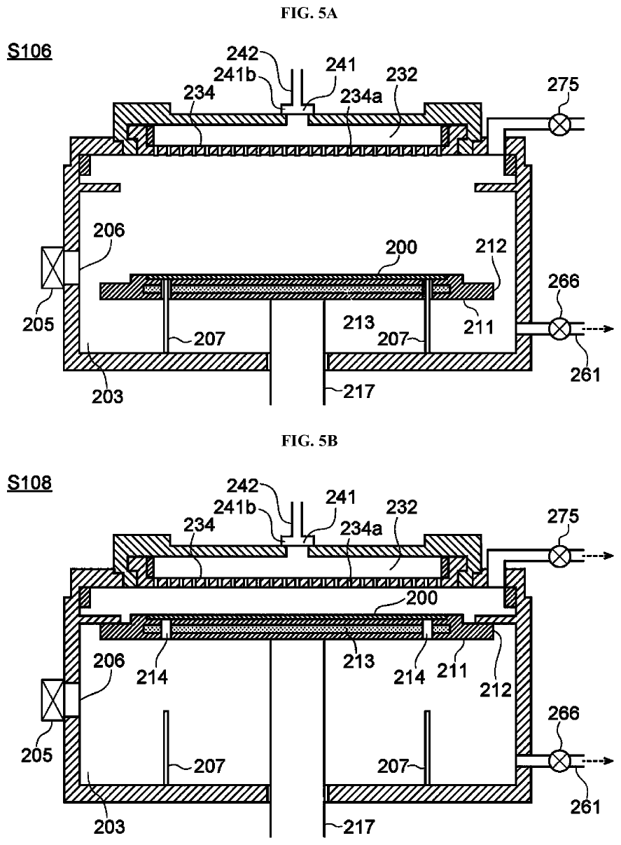

After a predetermined time has elapsed, the substrate mounting table 212 is elevated until the wafer 200 is placed on the substrate placing surface 211 as shown in FIG. 5A Then, the substrate mounting table 212 is further elevated until the wafer 200 reaches the wafer processing position as shown in FIG. 5B. The wafer processing position refers to a position at which the wafer 200 is processed by the process gas; and is, for example, a position at which a height of the surface of the substrate mounting table 212 is the same as a height of a partition wall 204.

<Desorbed Substance Removing Step: S108>

It is known that the film formed on the wafer 200 contains many impurities. The impurities may contain a substance such as constituents and reaction by-products of a gas supplied to the wafer 200 in a process chamber different from the process chamber 201 before the wafer 200 is loaded into the process chamber 201. For example, the impurities may contain the substance such as a fluoride and a carbon-based residue, which are derived from constituents of an etching gas such as sulfur hexafluoride (SF₆) gas and carbon tetrafluoride (CF₄) gas. A desorption of the impurities from the film is promoted by heating the wafer 200 to a high temperature.

Since a surface area of the film tends to increase with a recent miniaturization of the semiconductor device, an amount of the impurities also tends to increase. Therefore, when the wafer 200 is continuously heated, the desorption of the impurities is also continued. As a result, when a desorption amount of the impurities is greater than an exhaust amount of the impurities, the impurities may stagnate on the wafer 200. For example, the amount of the impurities stagnated in an atmosphere on the center of the wafer 200 where an exhaust efficiency is low is greater than the amount of the impurities stagnated in an atmosphere on an outer periphery of the wafer 200 where the exhaust efficiency is high. For example, when the source gas is supplied in such a state, the desorbed substance may stagnate between the source gas and the surface of the wafer 200. In such a case, the source gas cannot reach the surface of the wafer 200 or an amount of the source gas reaching the surface of the wafer 200 may be insufficient. Therefore, on the wafer 200, there are locations where the film can be formed and locations where the film cannot be formed. Therefore, it is difficult to uniformly process the wafer 200. Therefore, the yield may decrease.

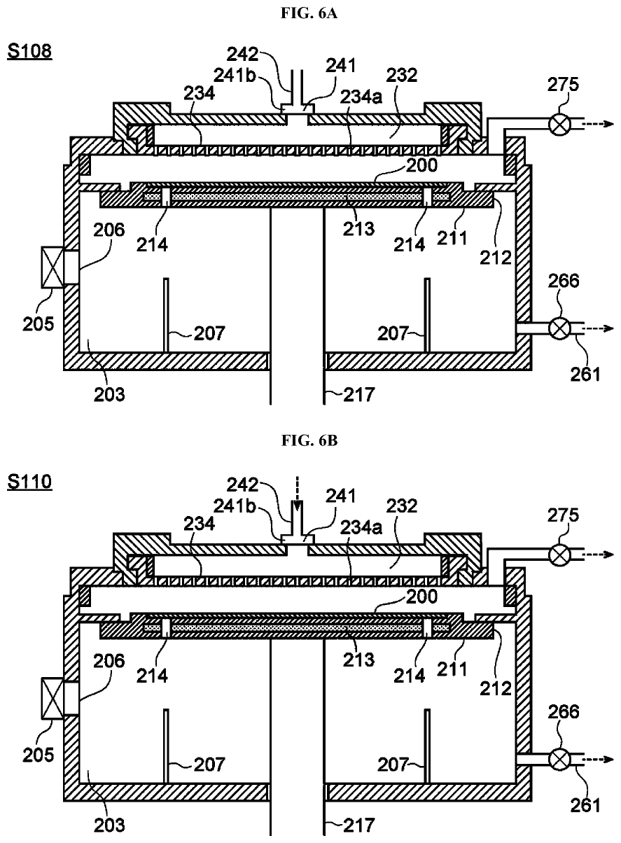

Therefore, in the present step, the desorbed substance is removed from the atmosphere on the surface of the wafer 200 before a supply of the process gas is started. Specifically, as shown in FIG. 6A, an inner atmosphere of the process chamber 201 is exhausted. Thereby, it is possible to remove the desorbed substance desorbed from the heated wafer 200. By removing the desorbed substance, it is possible to uniformly supply the DCS gas (which is the process gas to be supplied next) onto the wafer 200. In the above description, the desorbed substance is removed when the wafer processing position is reached. However, as long as the desorbed substance can be removed, it would be acceptable even if the wafer processing position is not reached. For example, the desorbed substance may be removed when the wafer 200 is between the wafer transfer position and the wafer processing position. More preferably, the desorbed substance is removed when the wafer processing position is reached at which the temperature of the wafer 200 is stable.

<Film-Forming Step: S110>

Subsequently, the film-forming step S110 will be described. Hereinafter, the film-forming step S110 will be described in detail with reference to FIG. 7. As the film-forming step S110, a cyclic process may be performed by repeating alternately supplying different process gases (that is, by repeatedly and alternately performing a first process gas supply step S202 and a second process gas supply step S206 described later).

<First Process Gas Supply Step: S202>

After the substrate mounting table 212 is moved to the wafer processing position as shown in FIG. 6B, the inner atmosphere of the process chamber 201 is exhausted through the exhaust pipe 262 to adjust the inner pressure of the process chamber 201 to a predetermined pressure. When the temperature of the wafer 200 is adjusted, since the dispersion plate 234 is already heated, an amount of a heat transfer from the heater 213 to the dispersion plate 234 is reduced. Therefore, it is possible to heat the wafer 200 quickly.

When the temperature of the wafer 200 reaches a predetermined temperature (for example, equal to or higher than 500° C. and equal to or lower than 600° C.) while adjusting the inner pressure of the process chamber 201 to the predetermined pressure, the first process gas such as the DCS gas is supplied to the process chamber 201 through the common gas supply pipe 242. By supplying the DCS gas onto the wafer 200 in the process chamber 201, a silicon-containing layer is formed on the wafer 200.

<Purge Step: S204>

After a supply of the DCS gas is stopped, the N₂ gas serving as the inert gas is supplied through the third gas supply pipe 245a to purge the process chamber 201. When purging the process chamber 201, with the valve 275 and the valve 277 open, the inner pressure of the process chamber 201 is adjusted (or controlled) to a predetermined pressure by the APC 276. On the other hand, all of the valves of the gas exhauster other than the valve 275 and the valve 277 are closed. As a result, the DCS gas that is not bonded to the wafer 200 in the first process gas supply step S202 is removed from the process chamber 201 by the DP 278 through the exhaust pipe 262.

In the purge step S204, a large amount of the purge gas may be supplied to improve the exhaust efficiency in order to remove the DCS gas remaining in the wafer 200, the process chamber 201 and the shower head buffer chamber 232.

More preferably, after the process chamber 201 is sufficiently purged by supplying thereto the N₂ gas through the third gas supply pipe 245a, the pressure control by the APC 276 is resumed. Further, the N₂ gas may be continuously supplied through the third gas supply pipe 245a to purge the shower head 230 and the process chamber 201.

<Second Process Gas Supply Step: S206>

After the shower head buffer chamber 232 and the process chamber 201 are completely purged, the second process gas supply step S206 is subsequently performed. In the second process gas supply step S206, with the valve 244d open, the NH₃ gas serving as the second process gas (second element-containing gas) is started being supplied into the process chamber 201 through the plasma generator 231 and the shower head 230. In the second process gas supply step S206, the MFC 244c is controlled such that a flow rate of the NH₃ gas is adjusted to a predetermined flow rate. For example, a supply flow rate of the NH₃ gas may be equal to or more than 1,000 sccm and equal to or less than 10,000 sccm. In addition, in the second process gas supply step S206, with the valve 245d of the third gas supplier 245 open, the N₂ gas is supplied through the third gas supply pipe 245a. By supplying the N₂ gas through the third gas supply pipe 245a, it is possible to prevent the NH₃ gas from entering the third gas supplier 245.

The NH₃ gas activated into a plasma state by the plasma generator 231 is supplied into the process chamber 201 through the shower head 230. The NH₃ gas supplied into the process chamber 201 reacts with the silicon-containing layer on the wafer 200. Thereby, the silicon-containing layer already formed on the wafer 200 is modified by the NH₃ gas activated into the plasma state. As a result, for example, a silicon nitride layer (also simply referred to as an “SiN layer”) containing silicon (Si) and nitrogen (N) is formed on the wafer 200.

After a predetermined time has elapsed from a start of the supply of the NH₃ gas, the valve 244d is closed to stop the supply of the NH₃ gas. For example, a supply time (time duration) of supplying the NH₃ gas may be equal to or more than 2 seconds and equal to or less than 20 seconds.

In the second process gas supply step S206, similar to the first process gas supply step S202, the inner pressure of the process chamber 201 is controlled (adjusted) by the APC 276 to become a predetermined pressure with the valve 275 and the valve 277 open. On the other hand, all of the valves of the gas exhauster other than the valve 275 and the valve 277 are closed.

The film-forming step S110 further includes the first processing step S104 and the second processing step S105.

<First Processing Step: S104>

In the first processing step S104, the wafer 200 is heated between the first temperature and the second temperature.

<Second Processing Step: S105>

In the second processing step S105, the temperatures of the heaters 224 and 225 (that is, the second heater) are set to be higher than those of the heaters 224 and 225 (that is, the second heater) when the first processing step S104 is performed such that the temperature deviation on the surface of the wafer 200 is within a predetermined temperature deviation range. Thereby, the activated process gas is supplied into the process chamber 201.

When a distribution of a plasma activity is configured such that the plasma activity over a center of the substrate mounting table 212 is higher than the plasma activity over an outer periphery of the substrate mounting table 212, and when a temperature of the substrate mounting table 212 is uniform, a film-forming result is affected by the distribution of the plasma activity. For example, in a case where the temperature of the substrate mounting table 212 (and the wafer 200 placed thereon) is controlled to a uniform temperature of 400° C., when the plasma is generated an atmosphere over a central portion of the substrate mounting table 212 (and the wafer 200 placed thereon) is similar to that obtained by heating the wafer 200 to 500° C.

In order to uniformize the characteristics of the film, it is preferable that a temperature of the outer periphery of the substrate mounting table 212 (and the wafer 200 placed thereon) is set to be higher than a temperature of the center of the substrate mounting table 212 (and the wafer 200 placed thereon) so as to cancel out the temperature deviation. Therefore, for example, the temperature of the outer periphery of the substrate mounting table 212 (and the wafer 200 placed thereon) may be controlled by the heater 213 of the substrate mounting table 212, or may be controlled by another heater.

In a case where the temperature of the outer periphery of the substrate mounting table 212 (and the wafer 200 placed thereon) is controlled by the heater 213 of the substrate mounting table 212, the heat capacity of the substrate mounting table 212 is large. Therefore, it takes time to return the temperature of the substrate mounting table 212 to its original temperature before the subsequent substrate processing while continuing to process a plurality of wafers including the wafer 200, and the manufacturing throughput of the semiconductor device is lowered. Therefore, according to the present embodiment, the heaters 224 and 225 serving as an example of the second heater are provided separately from the heater 213 of the substrate mounting table 212. Thereby, it is possible to efficiently heat the surface of the wafer 200 in a non-uniform manner. Further, it is also possible to uniformly perform a plasma process and suppress the warp of the wafer 200.

Specifically, the controller 280 (that is, the control structure) may change the pre-set value of the temperature deviation based on the substrate data including at least one among the thickness distribution of the film formed on the wafer 200 and the wafer etching rate (WER). More specifically, based on the substrate data including at least one among the thickness distribution of the film formed on the wafer 200 and the wafer etching rate, the controller 280 (that is, the control structure) may change at least one among the pre-set temperature value of the heater 213 (that is, the first heater) and the pre-set temperature value of the heaters 224 and 225 (that is, the second heater).

The amount of the active species may affect the film characteristics. However, it is difficult to measure the amount of the active species. Therefore, at least one among the heater 213 and the heaters 224 and 225 are feedback-controlled based on the film characteristics. For example, when the wafer etching rate on the outer peripheral portion of the wafer 200 is high, the temperatures of the heaters 224 and 225 (that is, the second heater) are elevated. Thereby, it is possible to improve the accuracy of controlling the temperature distribution on the surface of the wafer 200.

<Purge Step: S208>

After the supply of the NH₃ gas is stopped, the purge step S208 similar to the purge step S204 described above is performed. The operations of the components of the substrate processing apparatus 100 in the purge step S208 are similar to those of the components in the purge step S204. Therefore, the detailed descriptions of the purge step S208 are omitted.

<Determination Step: S210>

In the determination step S210, the controller 280 determines whether a cycle including the first process gas supply step S202, the purge step S204, the second process gas supply step S206 and the purge step S208 has been performed a predetermined number of times (n times). By performing the cycle the predetermined number of times, the SiN film of a desired thickness is formed on the wafer 200.

<Step of Moving Substrate to Wafer Transfer Position: S112>

Referring back to FIG. 3, after the SiN film of the desired thickness is formed on the wafer 200, the substrate mounting table 212 is lowered until the wafer 200 is moved to the wafer transfer position. When the substrate mounting table 212 is lowered, the inert gas is supplied into the process chamber 201 through the third gas supplier 245 so as to adjust the inner pressure of the process chamber 201 to a predetermined pressure.

However, when the substrate mounting table 212 is lowered, the dispersion plate 234 is less likely to be affected by the temperature of the heater 213. As a result, a temperature of the dispersion plate 234 may be lowered. As described above, it is preferable that the dispersion plate 234 is heated in the film-forming step S110, but when the temperature of the dispersion plate 234 is lowered, it takes time to heat the dispersion plate 234 to a desired temperature again. Therefore, it takes time to heat the wafer 200 to a desired temperature.

<Substrate Unloading Step: S114>

In the substrate unloading step S114, the processed wafer 200 is transferred (unloaded) out of the process vessel 202 in the order reverse to that of the substrate loading and placing step S102. When an unprocessed wafer 200 is present, the unprocessed wafer 200 is loaded into the process vessel 202 in the order same as that of the substrate loading and placing step S102. Thereafter, the steps S105 through S114 are performed to the loaded wafer 200.

<Method of Manufacturing Semiconductor Device>

A method of manufacturing a semiconductor device according to the technique of the present disclosure is performed using the substrate processing apparatus 100 described above. The method of manufacturing the semiconductor device may include: (a) the first processing step S104 of heating the wafer (substrate) 200 to at least a temperature between the first temperature and the second temperature; and (b) the second processing step S105 of supplying the process gas activated by the plasma generator 231 while setting the temperature of the second heater to be higher than that of the second heater at which the first processing step S104 is performed such that the temperature deviation occurring in a temperature range between the first temperature and the second temperature on the surface of the wafer 200 is within the predetermined temperature deviation range.

<Program>

A program according to the technique of the present disclosure is a program that causes, by a computer, the substrate processing apparatus 100 to perform: (a) a first processing sequence of heating the wafer (substrate) 200 to at least a temperature between the first temperature and the second temperature; and (b) a second processing sequence of supplying the process gas activated by the plasma generator 231 while setting the temperature of the second heater to be higher than that of the second heater at which the first processing sequence is performed such that the temperature deviation occurring in a temperature range between the first temperature and the second temperature on the surface of the wafer 200 is within the predetermined temperature deviation range.

<Other Embodiments>

While the technique of the present disclosure is described in detail by way of the embodiment described above, the technique of the present disclosure is not limited thereto. The technique of the present disclosure may be modified in various ways without departing from the scope thereof.

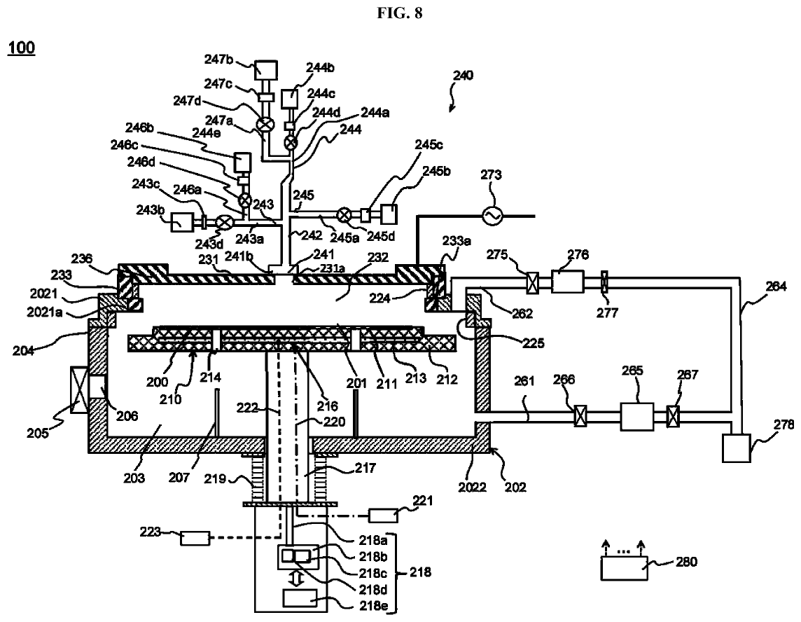

For example, the above-described embodiment is described by way of an example in which the gas supplier 240 includes the shower head 230. However, the technique of the present disclosure is not limited thereto. For example, as shown in FIG. 8, the gas supplier 240 according to a second embodiment of the present disclosure may be provided without the shower head 230.

For example, the above-described embodiment is described by way of an example in which the SiN film is formed on the wafer 200 by alternately supplying, in the film-forming step S110 performed by the substrate processing apparatus 100, the DCS gas serving as the first element-containing gas (first process gas) and the NH₃ gas serving as the second element-containing gas (second process gas). However, the technique of the present disclosure is not limited thereto. For example, the process gases used in the film-forming step S110 are not limited to the DCS gas and the NH₃ gas. That is, the technique of the present disclosure may also be applied to other film-forming steps wherein other gases are used to form different films, or three or more different process gases are supplied in turn to form a film. Specifically, instead of silicon, for example, an element such as titanium (Ti), zirconium (Zr) and hafnium (Hf) may be used as the first element. In addition, instead of nitrogen (N), for example, an element such as oxygen (O) or carbon (C) may be used as the second element.

For example, the above-described embodiment is described by way of an example in which a film-forming process is performed in the substrate processing apparatus 100. However, the technique of the present disclosure is not limited thereto. That is, the technique of the present disclosure can be applied not only to the film-forming process of forming the film exemplified in the above-described embodiment but also to other film-forming processes of forming another film. For example, the technique of the present disclosure may also be applied another substrate processing such as an annealing process, a diffusion process, an oxidation process, a nitridation process and a lithography process. The technique of the present disclosure may also be applied to other substrate processing apparatuses such as an annealing apparatus, an etching apparatus, an oxidation apparatus, a nitridation apparatus, an exposure apparatus, a coating apparatus, a drying apparatus, a heating apparatus, an apparatus using the plasma and combinations thereof. Further, one or more constituents of the above-described examples may be substituted with one or more constituents of other examples, or may be added to other examples. Further, a part of one or more constituents of the above-described examples may be omitted, or substituted with or added by other constituents.

According to some embodiments of the present disclosure, it is possible to improve the uniformity of the surface temperature of the substrate in the plasma process.

What is claimed is:

1. A substrate processing apparatus comprising:
a process chamber in which a substrate is accommodated;
a substrate support provided in the process chamber and on which the substrate is placed;
a first heater provided in the substrate support and configured to heat the substrate;
a second heater configured to heat an outer periphery of the substrate;
a gas supplier through which a process gas is supplied onto the substrate;
a plasma generator configured to activate the process gas in the process chamber; and
a controller configured to be capable of controlling the first heater, the second heater, the gas supplier and the plasma generator to perform:
(a) heating the substrate to at least a temperature between a first temperature and a second temperature; and
(b) supplying the process gas activated by the plasma generator while setting a temperature of the second heater to be higher than that of the second heater at which (a) is performed such that a temperature deviation on a surface of the substrate is within a predetermined temperature deviation range.

2. The substrate processing apparatus of claim 1, wherein the gas supplier is provided so as to face the substrate, and
the plasma generator is provided in the gas supplier.

3. The substrate processing apparatus of claim 1, wherein the second heater is provided at a location at which the second heater is capable of heating an upper portion of the process chamber above the first heater of the substrate support elevated to a processing position.

4. The substrate processing apparatus of claim 2, wherein the second heater is provided at a location at which the second heater is capable of heating an upper portion of the process chamber above the first heater of the substrate support elevated to a processing position.

5. The substrate processing apparatus of claim 1, wherein the second heater is provided at a wall of the process chamber.

6. The substrate processing apparatus of claim 2, wherein the second heater is provided at a wall of the process chamber.

7. The substrate processing apparatus of claim 3, wherein the second heater is provided at a wall of the process chamber.

8. The substrate processing apparatus of claim 4, wherein the second heater is provided at a wall of the process chamber.

9. The substrate processing apparatus of claim 1, wherein the second heater is provided in the gas supplier.

10. The substrate processing apparatus of claim 2, wherein the second heater is provided in the gas supplier.

11. The substrate processing apparatus of claim 3, wherein the second heater is provided in the gas supplier.

12. The substrate processing apparatus of claim 5, wherein the second heater is provided in the gas supplier.

13. The substrate processing apparatus of claim 1, wherein the second heater is configured as a lamp heater.

14. The substrate processing apparatus of claim 2, wherein the second heater is configured as a lamp heater.

15. The substrate processing apparatus of claim 3, wherein the second heater is configured as a lamp heater.

16. The substrate processing apparatus of claim 1, wherein the controller is configured to be capable of changing a pre-set value of the temperature deviation based on substrate data including at least one of a thickness distribution of a film formed on the substrate or a wafer etching rate.

17. The substrate processing apparatus of claim 1, wherein, based on substrate data including at least one of a thickness distribution of a film formed on the substrate or a wafer etching rate, the controller is configured to be capable of changing at least one of a pre-set temperature value of the first heater or a pre-set temperature value of the second heater.

18. A substrate processing method related to a substrate processing apparatus comprising a process chamber in which a substrate is accommodated; a substrate support provided in the process chamber and on which the substrate is placed; a first heater provided in the substrate support and configured to heat the substrate; a second heater configured to heat an outer periphery of the substrate; a gas supplier through which a process gas is supplied onto the substrate; a plasma generator configured to activate the process gas in the process chamber; and a controller configured to be capable of controlling the first heater, the second heater, the gas supplier and the plasma generator, the method comprising:
(a) heating the substrate accommodated in the process chamber to at least a temperature between a first temperature and a second temperature; and
(b) supplying the process gas activated by the plasma generator while setting a temperature of the second heater to be higher than that of the second heater at which (a) is performed such that a temperature deviation between the first temperature and the second temperature on a surface of the substrate is within a predetermined temperature deviation range.

19. A method of manufacturing a semiconductor device, comprising the substrate processing method of claim 18.

20. A non-transitory computer-readable recording medium storing a program related to a substrate processing apparatus comprising a process chamber in which a substrate is accommodated; a substrate support provided in the process chamber and on which the substrate is placed; a first heater provided in the substrate support and configured to heat the substrate; a second heater configured to heat an outer periphery of the substrate; a gas supplier through which a process gas is supplied onto the substrate; a plasma generator configured to activate the process gas in the process chamber; and a controller configured to be capable of controlling the first heater, the second heater, the gas supplier and the plasma generator, wherein the program causes, by a computer, the substrate processing apparatus to perform:
(a) heating the substrate accommodated in the process chamber to at least a temperature between a first temperature and a second temperature; and
(b) supplying the process gas activated by the plasma generator while setting a temperature of the second heater to be higher than that of the second heater at which (a) is performed such that a temperature deviation between the first temperature and the second temperature on a surface of the substrate is within a predetermined temperature deviation range.
